(19) United States
(12) Patent Application Publication
(10) Pub. No.: US 2013/0033260 A1
(43) Pub. Date: Feb. 7, 2013

(54) CURRENT SENSOR

(71) Applicant: ALPS GREEN DEVICES CO., LTD., Tokyo (JP)

(72) Inventor: Masatoshi NOMURA, Miyagi-ken (JP)

(73) Assignee: ALPS GREEN DEVICES CO., LTD., Tokyo (JP)

(21) Appl. No.: 13/650,069

(22) Filed: Oct. 11, 2012

Related U.S. Application Data
(63) Continuation of application No. PCT/JP2011/059445, filed on Apr. 15, 2011.

(30) Foreign Application Priority Data
Apr. 26, 2010 (JP) 2010-100948

(51) Int. Cl. G01R 33/038; G01R 33/09

(52) U.S. Cl. 324/252; 324/258

(57) ABSTRACT

A current sensor includes a pair of magnetic balance sensors and a switching circuit. The magnetic balance sensors each include a magnetic sensor element and a feedback coil. The magnetic sensor element varies in characteristics due to an induction field caused by measurement current. The feedback coil is disposed near the magnetic sensor element and produces a canceling magnetic field canceling out the induction field. Each of the magnetic balance sensors outputs, as a sensor output, a value corresponding to current flowing through the feedback coil when a balanced state in which the induction field and the canceling magnetic field cancel each other out is reached after the feedback coil is energized. The switching circuit turns on/off one of the magnetic balance sensors.

### CLAIM OF PRIORITY

This application is a Continuation of International Application No. PCT/JP2011/059445 filed on Apr. 15, 2011, which claims benefit of Japanese Patent Application No. 2010-100948 filed on Apr. 26, 2010. The entire contents of each application noted above are hereby incorporated by reference.

### BACKGROUND OF THE INVENTION

1. Field of the Invention

The present invention relates to a current sensor employing a magnetoresistive element.

2. Description of the Related Art

In electric cars, a motor is driven using power generated by an engine. The magnitude of current for driving the motor is detected, for example, using a current sensor. One example of such current sensors is a sensor which includes a magnetic core that has a cutout portion (core gap) in a portion thereof and that is disposed around a conductor, and a magnetic sensor element disposed in the core gap (see Japanese Unexamined Patent Application Publication No. 2007-212306). In this current sensor, a magnetic field proportional to a measurement current passes through the core gap due to magnetic lines of force produced in the magnetic core. The magnetic sensor element converts this magnetic field into a voltage signal, and an amplifying circuit amplifies the output voltage from the magnetic sensor element and produces an output voltage proportional to the measurement current.

Recently, as the output and the performance of electric cars have increased, a value of current to be used has been raised. Accordingly, it is required to avoid magnetic saturation occurring when a large current flows. To avoid magnetic saturation, the magnetic core needs to be made larger. However, a larger magnetic core unfortunately results in an increase in the size of the current sensor itself. To solve such an issue of a current sensor employing a magnetic core, a current sensor employing a magnetoresistive element instead of a magnetic core has been proposed (see WO98/007165).

One example of such a current sensor is a magnetic balance sensor. In a magnetic balance current sensor, when a measurement current flows, a magnetic detection device produces an output voltage due to a magnetic field in accordance with the current. The magnetic detection device outputs a voltage signal which is converted into a current so that the current is fed back to a feedback coil. The feedback coil produces a magnetic field (canceling magnetic field), and the canceling magnetic field and the magnetic field produced by the measurement current cancel each other out so that the resulting magnitude of the magnetic fields is constantly equal to zero. The current sensor converts the feedback current which flows through the feedback coil at that time into a voltage and outputs the resulting voltage.

A configuration using a magnetoresistive element instead of a magnetic core is subjected to an influence of the external magnetic field, and therefore needs a magnetic shield to reduce the influence, resulting in an increase in difficulty in the design and an increase in complexity of the configuration. This leads to a problem of an increase in cost of manufacture. Thus, a method has been proposed in which two or more magnetic sensor elements are used to cancel out the external magnetic field by using a differential.

However, a magnetic balance sensor employing a magnetoresistive element consumes more power than a sensor employing another system such as a shunt resistance system, in a region in which a measurement current is relatively small. Thus, multiple magnetic balance sensors which are used to cancel the external magnetic field causes a problem of increased power consumption particularly in a region in which the measurement current is relatively small.

### SUMMARY OF THE INVENTION

The present invention has been made in view of the above-described problem, and provides a current sensor which achieves reduction in size with a simple configuration and which can measure a small measurement current with low power consumption and high accuracy.

A current sensor according to an aspect of the present invention includes multiple magnetic balance sensors, each of which includes a magnetic sensor element and a feedback coil, and a switching unit. The magnetic sensor element varies in characteristics due to an induction field caused by measurement current. The feedback coil is disposed near the magnetic sensor element, and produces a canceling magnetic field canceling out the induction field. Each of the magnetic balance sensors outputs, as a sensor output, a value corresponding to current flowing through the feedback coil when a balanced state in which the induction field and the canceling magnetic field cancel each other out is reached after the feedback coil is energized. The switching unit turns on/off magnetic balance sensors other than one of the multiple magnetic balance sensors.

In this configuration, a single current sensor turns on/off magnetic balance sensors other than one magnetic balance sensor, enabling the size to be reduced with a simple configuration and enabling a measurement current to be detected with low power consumption.

In the current sensor according to the aspect of the present invention, it is preferable that a pair of magnetic balance sensors be disposed so as to face each other with a conductor which is interposed therebetween and through which the measurement current flows, and that sensing axis directions of the magnetic sensor elements in the pair of magnetic balance sensors be identical. This configuration causes an influence of the external magnetic field such as the earth magnetism to be canceled, enabling a current to be measured with higher accuracy.

In the current sensor according to the aspect of the present invention, it is preferable that the switching unit turn on/off the magnetic balance sensors other than one of the multiple magnetic balance sensors in accordance with an external signal. This configuration enables the power consumption of a current sensor to be reduced at any timing when a user wants to save power, for example, in the sleep mode, achieving compatibility between a wide measurement range obtained by the magnetic balance system and power saving.

In the current sensor according to the aspect of the present invention, it is preferable that the magnetic balance sensors other than one of the multiple magnetic balance sensors be turned off in a range of a relatively small measurement current.

In the current sensor according to the aspect of the present invention, it is preferable that a signal which indicates an on/off state of the magnetic balance sensors other than one of the multiple magnetic balance sensors be output to the outside. This configuration enables the current mode of the current sensor to be checked.

In the current sensor according to the aspect of the present invention, it is preferable that the magnetic sensor element be a magnetoresistive element. This configuration enables the sensing axis to be easily disposed in the direction parallel to the substrate surface on which the current sensor is installed, and enables a planar coil to be used.

A battery according to another aspect of the present invention includes a battery body provided with a current line, and the above-described current sensor attached to the current line.

### BRIEF DESCRIPTION OF THE DRAWINGS

FIG. 1 is a diagram illustrating a current sensor including one magnetic balance sensor according to an embodiment of the present invention;

FIG. 2 is a diagram illustrating a configuration of magnetic balance sensors according to an embodiment of the present invention;

FIG. 3 is a diagram illustrating a current sensor according to an embodiment of the present invention;

FIG. 4 is a diagram illustrating exemplary power consumption of a current sensor according to an embodiment of the present invention;

FIG. 5 is a diagram illustrating exemplary power consumption of a current sensor according to an embodiment of the present invention;

FIG. 6 is a diagram illustrating exemplary power consumption of a current sensor according to an embodiment of the present invention; and

FIG. 7 is a diagram for explaining what kinds of batteries are used when a current sensor according to an embodiment of the present invention is applied to batteries.

### DESCRIPTION OF THE PREFERRED EMBODIMENTS

An Embodiment of the present invention will be described in detail below with reference to the accompanying drawings. Herein, a current sensor will be described which includes two magnetic balance sensors, one of which continuously operates, and the other of which is turned on/off. In the present invention, a current sensor may include three magnetic balance sensors or more.

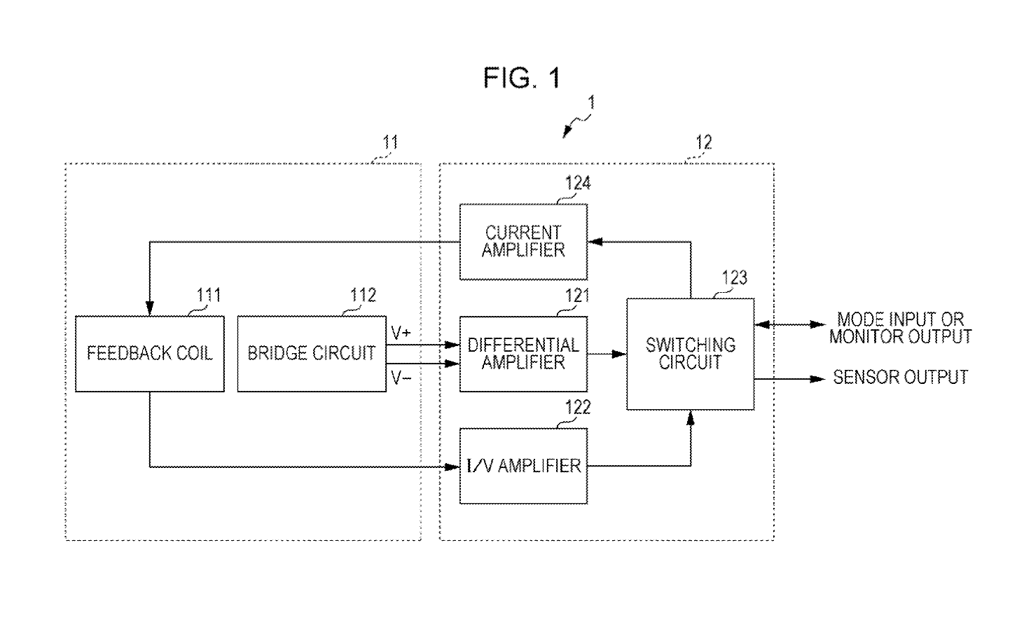

FIG. 1 is a diagram illustrating a current sensor including one magnetic balance sensor, according to the embodiment of the present invention. In the embodiment, a current sensor 1 illustrated in FIG. 1 is disposed near a current line through which a measurement current flows. The current sensor 1 mainly includes a sensing unit 11 and a controller 12.

The sensing unit 11 includes a feedback coil 111 which is disposed in such a manner that a magnetic field can be produced in a direction in which a magnetic field caused by the measurement current is canceled, and a bridge circuit 112 which includes two magnetoresistive elements, which are magnetic detection devices, and two fixed resistance elements. The controller 12 includes a differential amplifier 121 which amplifies a differential output from the bridge circuit 112, a current amplifier 124 which controls a feedback current flowing through the feedback coil 111, an I/V amplifier 122 which converts the feedback current into voltage, and a switching circuit 137 which turns on/off one of the magnetic balance sensors.

The feedback coil 111 is disposed near the magnetoresistive elements in the bridge circuit 112, and produces a canceling magnetic field which cancels out an induction field produced by the measurement current. Examples of the magnetoresistive elements in the bridge circuit 112 include a giant magneto resistance (GMR) element and a tunnel magneto resistance (TMR) element. The magnetoresistive elements vary in resistance due to application of the induction field caused by the measurement current. The two magnetoresistive elements and the two fixed resistance elements constitute the bridge circuit 112, thereby achieving a high-sensitivity current sensor. The bridge circuit 112 has two outputs with which a voltage difference is produced in accordance with the induction field caused by the measurement current. By using a magnetoresistive element, the sensing axis is easily disposed in a direction parallel to the substrate surface on which the current sensor is installed, enabling a planar coil to be used.

The bridge circuit 112 has two outputs with which a voltage difference is produced in accordance with the induction field caused by the measurement current. The differential amplifier 121 amplifies the two outputs of the bridge circuit 112. In this case, the current amplifier 124 supplies the feedback coil 111 with a current into which the amplified output has been converted, i.e., a feedback current. This feedback current corresponds to the voltage difference which is in accordance with the induction field. At that time, the feedback coil 111 produces a canceling magnetic field which cancels out the induction field. Then, the I/V amplifier 122 converts, into voltage, the current that flows through the feedback coil 111 when a balanced state is reached in which the induction field and the canceling magnetic field cancel each other out, and this voltage is output as a sensor output.

In the current amplifier 124, by setting the supply voltage to a value close to a value obtained through the following expression, the reference voltage for the I/V conversion+(the maximum value of the rating of the feedback coil resistance×the feedback coil current at full scale), the feedback current is automatically restricted, achieving an effect of protection of the magnetoresistive elements and the feedback coil. According to the embodiment, a differential between the two outputs in the bridge circuit 112 is amplified to be used for the feedback current. Alternatively, only a midpoint potential may be output from the bridge circuit 112, and the feedback current may be produced on the basis of the potential difference between the midpoint potential and a predetermined reference potential.

How to turn on/off one of the magnetic balance sensors will be described. The power of a magnetic balance sensor is consumed mainly due to the supply of power to the feedback coil 111. However, the bridge circuit 112 also consumes power as small as about 3% of that consumed in the coil portion. In the case where the present invention is to be applied to a system in which a measurement current does not often change rapidly and in which the power consumption is to be reduced as much as possible in the power-saving mode (power stop mode), it is desirable to stop the supply of power to the bridge circuit as well. On the other hand, in a system in which a power-saving effect such as reduction in power using a shunt is achieved only by stopping the power to the coil portion, it is advantageous to continue to supply power to the bridge circuit because this has an advantage that when power is turned on, stability is achieved in a shorter time period. Hereinafter, an example of the latter case will be described.

The switching circuit 123 turns on/off one of magnetic balance sensors. That is, the switching circuit 123 switches between supply and stop of power to the feedback coil 111. Thus, the switching circuit 123 controls circuits in such a manner that a magnetic field, i.e., a canceling magnetic field, which cancels out the induction field caused by the measurement current which flows through the current line is produced in the normal mode, i.e., power energization mode, and that the canceling magnetic field is not produced in the power-saving mode, i.e., power stop mode. That is, the switching circuit 123 turns on/off the feedback current.

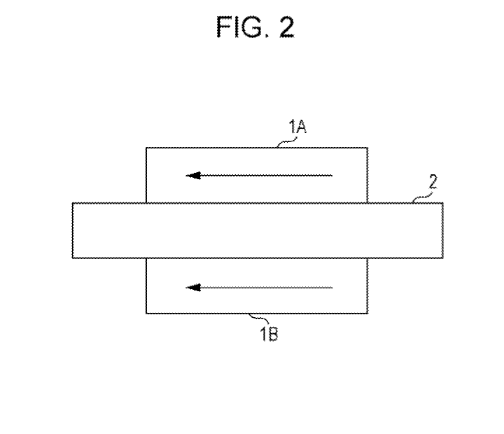

According to the embodiment, two (i.e., a pair of) magnetic balance sensors having the above-described configuration are disposed so as to face each other with a current line which is interposed therebetween and through which a measurement current flows, and the sensing axis directions of the magnetoresistive elements in the two magnetic balance sensors are the same. FIG. 2 is a diagram illustrating a configuration of magnetic balance sensors according to the embodiment of the present invention. In the configuration illustrated in FIG. 2, two magnetic balance sensors 1A and 1B are disposed so as to be opposite each other with a current line 2 which is interposed therebetween and through which a measurement current flows.

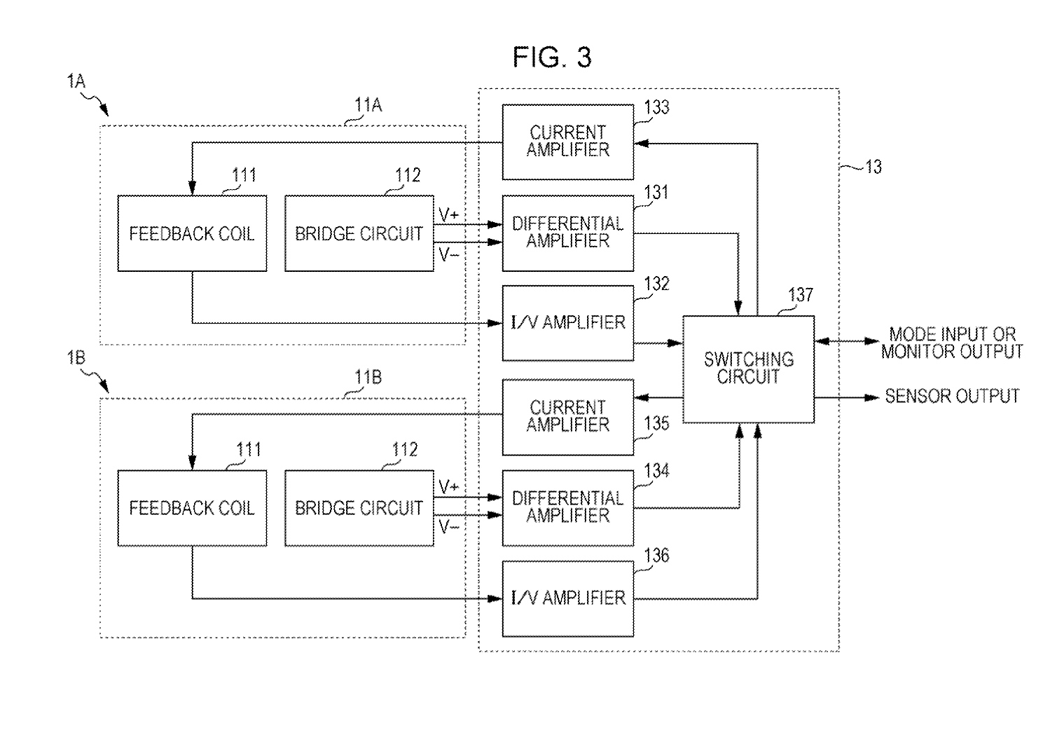

As illustrated in FIG. 3, sensing units 11A and 11B each include the feedback coil 111 which winds in a direction in which a magnetic field produced by the measurement current is canceled, and the bridge circuit 112 which includes two magnetoresistive elements, which are magnetic detection devices, and two fixed resistance elements. A controller 13 includes a differential amplifier 131 which amplifies a differential output from the bridge circuit 112 in the sensing unit 11A, a current amplifier 133 which controls a feedback current flowing through the feedback coil 111 in the sensing unit 11A, an I/V amplifier 132 which converts the feedback current in the sensing unit 11A into voltage, a differential amplifier 134 which amplifies a differential output from the bridge circuit 112 in the sensing unit 11B, a current amplifier 135 which controls a feedback current flowing through the feedback coil 111 in the sensing unit 11B, an I/V amplifier 136 which converts the feedback current in the sensing unit 11B into voltage, and a switching circuit 137 which turns on/off the supply of power to the feedback coil 111, i.e., turns on/off one of the magnetic balance sensors.

Components in the circuits illustrated in FIG. 3 are the same as those in FIG. 1, and will not be described in detail. In the configuration illustrated in FIG. 3, the switching circuit 137 performs switching control to turn on/off one of the magnetic balance sensors 1A and 1B (supply/stop of power to the feedback coil 111). In the normal mode, the switching circuit 137 outputs a differential between the voltages of the I/V amplifiers 132 and 136 as a sensor output. In the power-saving mode, the switching circuit 137 outputs the voltage of the magnetic balance sensor that is operating, as a sensor output. Such a configuration achieves the following. In the normal mode, since the magnetoresistive elements of the two magnetic balance sensors 1A and 1B have the same sensing axis direction, the external magnetic field such as the earth magnetism is canceled, enabling a current to be measured with higher accuracy. In a state in which little measurement current flows, the power-saving mode (i.e., by turning off the power of magnetic balance sensors other than one magnetic balance sensor) enables the power consumption of the current sensor to be reduced. In the normal mode, all other magnetic balance sensors are turned on with the timing at which the magnetic balance sensor that is continuously turned on detects a current.

In the normal mode, the magnetic balance sensors measure the primary current magnetic field in opposite directions in terms of the polarity, and measure the external magnetic field such as the earth magnetism or an element offset in the same directions. Thus, by obtaining the difference between them, only the primary current magnetic field can be extracted with double sensitivity, achieving high accuracy as a current sensor. Note that use of two or more magnetic balance sensors further increases the accuracy in calculation of cancellation of the external magnetic field.

As described above, a magnetic balance current sensor employing GMR elements consumes more power than other systems such as a shunt resistance when a measurement current is small. Accordingly, in the present invention, magnetic balance sensors other than one magnetic balance sensor are turned off in a relatively small measurement current range in order to reduce the power consumption. That is, one of the magnetic balance sensors is turned off in this embodiment.

Accordingly, the switching circuit 137 performs threshold determination for measurement current to switch between the mode in which only one magnetic balance sensor operates, i.e., the power-saving mode, and the mode in which all magnetic balance sensors operate, i.e., the normal mode (i.e., mode-switching). Specifically, the power-saving mode is turned on when a measurement current is relatively small, and the normal mode is turned on when a measurement current is larger than that. At that time, the threshold for measurement current is preferably set so as to exhibit hysteresis in order to avoid frequent switching.

The switching circuit 137 may switch between the power-saving mode and the normal mode (i.e., turn on/off the magnetic balance sensors other than one sensor) in accordance with an external signal. This enables the power consumption of the current sensor to be suppressed at any timing when a user wants to save power, such as in the sleep mode. In this case, a mode signal is input to the switching circuit 137 from the outside (i.e., a mode input). In this case, it is desirable to prepare a protection function such as a function in which the mode is not actually switched when the measurement current which causes magnetic saturation in the GMR element flows. In addition, a mode output or the like described below may be also used so that the current state can be grasped better.

In the case where the mode is automatically switched, the switching circuit 137 may output, to the outside, information about which mode is being used to measure the measurement current, i.e., a signal indicating whether the power-saving mode or the normal mode is being used (a signal indicating the on/off state of the magnetic balance sensor). This enables the current mode of the current sensor to be checked. In this case, the switching circuit 137 is connectable to an external monitor. In the case where the switching circuit 137 automatically switches the mode, the switching circuit 137 may perform the threshold determination for measurement current, and switch the mode on the basis of the result. Alternatively, the switching circuit 137 may switch the mode on the basis of information obtained from an apparatus in which the current sensors are installed.

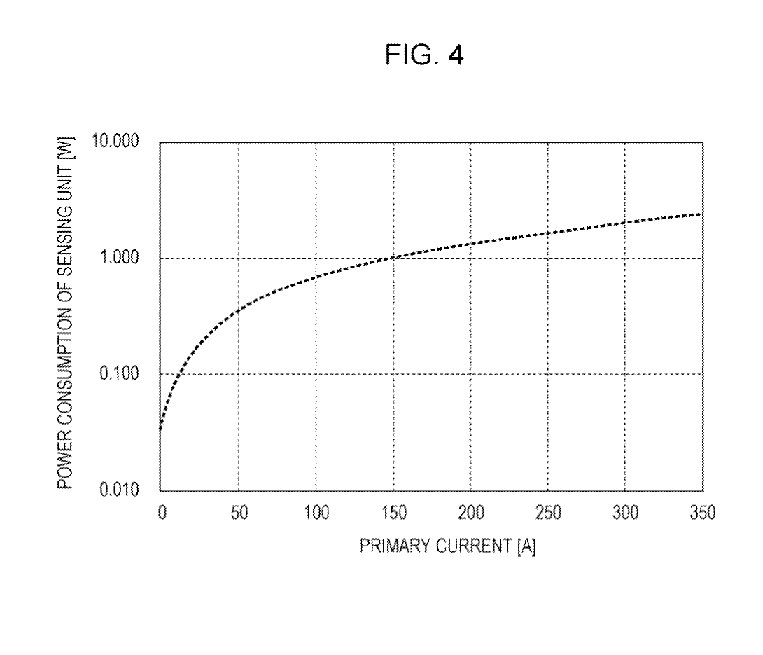

An example of switching between the power-saving mode and the normal mode in the current sensor according to the embodiment of the present invention will be described. FIG. 4 illustrates exemplary power consumption of a magnetic balance sensor employing a GMR element, i.e., a GMR magnetic balance system. As described above, a magnetic balance sensor has a problem in that the power consumption is larger than those of other systems such as a shunt resistor when a measurement current is small. The magnitude of a magnetic field caused by a primary current (measurement current) I [A] is calculated as I×0.2 [mT] at a position of 1 mm away from the center of the current in the case of a line conductor. In contrast, the earth magnetism has an approximately constant magnitude of several tens [μT]. Therefore, a coil current having a magnitude which corresponds to the primary current of several hundreds [mA] constantly flows.

An example will be described in which the current sensor according to the embodiment of the present invention is applied to a battery current sensor in an electric car or a hybrid car. This case is regarded as an example in which a large current mode and a small current mode that is other than the large current mode are clearly separated from each other during operation. For example, a hybrid car has a motor having a rating of 60 kW, 28 batteries connected in series, and a voltage of 201.6 V. In this case, a battery current of approximately 300 A flows during the rated operation of the motor. In contrast, the power consumption required while the car is being stopped depends mainly on electric components. The total of the power consumptions for the electric components is 87 A (12 V), which corresponds approximately to 5 A in terms of the battery current after current-voltage conversion.

Accordingly, a threshold used to turn on all of the magnetic balance sensors is set to 20 A which is much larger than 5 A and which is much smaller than 300 A. In contrast, a threshold used to turn off the magnetic balance sensors other than one magnetic balance sensor is set so as to exhibit hysteresis in order to avoid frequent switching, and is preferably set, for example, to 10 A which is moderately apart with respect to 20 A and 5 A. These thresholds are large enough for the external magnetic field such as the earth magnetism which corresponds to a primary current of several hundreds [mA], and are values with which a malfunction caused by a disturbance can be suppressed.

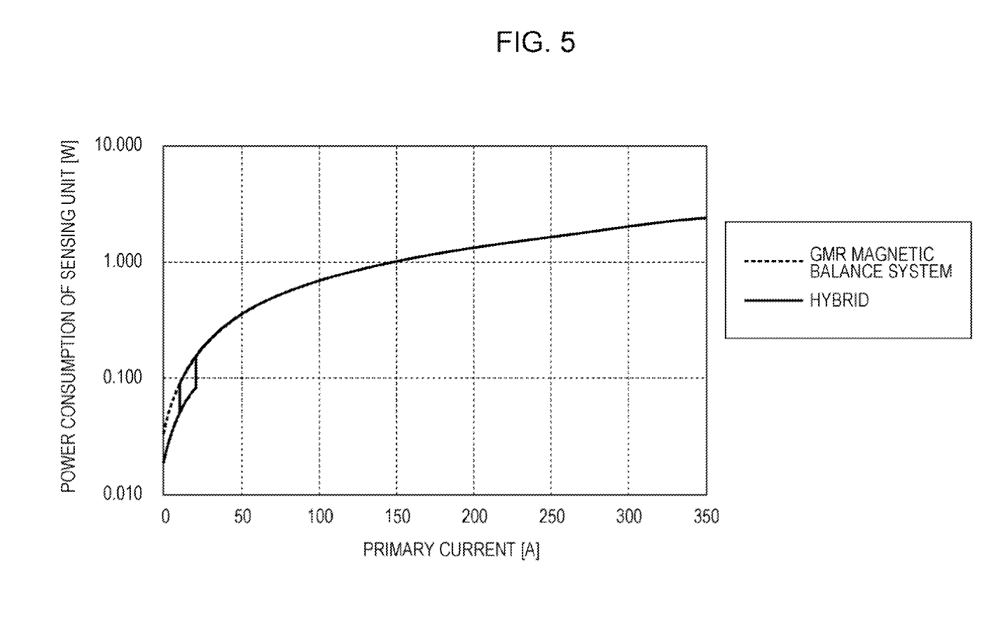

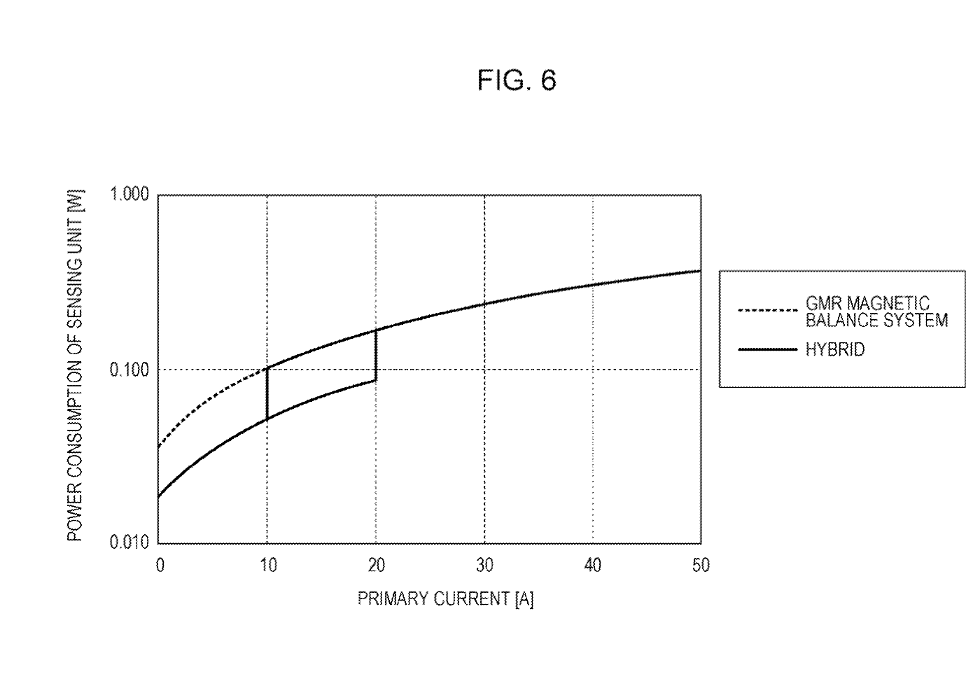

Under the above-described condition, the power consumption of the current sensor (indicated by Hybrid) according to the embodiment of the present invention is illustrated in FIGS. 5 and 6. FIG. 6 is an enlarged diagram illustrating the portion in which the switching is performed in FIG. 5. As clear from FIGS. 5 and 6, the mode is switched by using a measurement current value of 20 A as a threshold, whereby an advantage of the GMR magnetic balance sensor that high-accuracy measurement is performed in a wide measurement range is utilized and the power consumption is decreased when a measurement current is small, for example, when a car is being stopped.

In the case of a hybrid car, battery current is direct current. However, in the case where alternating current such as current from a household power supply is measured, the configuration according to the embodiment of the present invention can be also applied. In this case, for example, thresholds are set in such a manner that the second and following magnetic balance sensors are turned off when the maximum value, i.e., a peak value, of the measurement current becomes lower than the current range for the power-saving mode, e.g., 10 A, and that, in contrast, all of the magnetic balance sensors are turned on when the measurement current exceeds 20 A which is more than 10 A and which is in the current range in which no magnetic saturation occur in the current sensor even when the magnetic balance sensors are turned on. The mode switching control of alternating current is different from that of direct current in that only the maximum value in the alternating-current fluctuations is used for the determination. While all of the magnetic balance sensors are turned on and operating, the magnetic balance sensors operate even for all of the time periods in which a current value becomes 10 A or smaller in the alternating-current fluctuation period. This prevents frequent on/off switching of the magnetic balance sensors, achieving an effect that the current sensor can quickly follow a change in current which becomes larger. On the other hand, a threshold which is used to turn off the second and following magnetic balance sensors and which is properly set to, for example, 10 A achieves an effect of suppression of current consumption in the power-saving mode, which is the original aim, even when an effect of suppression of current consumption is not sufficiently achieved during operation in the state in which all of the magnetic balance sensors are on. In this case, the distinction from the disturbance magnetic field such as the earth magnetism is easily made by observing only alternating-current components in a magnetic field to be detected because the disturbance magnetic field is constituted mainly by direct-current components.

Thus, the current sensor according to the embodiment of the present invention switches between the normal mode, i.e., the mode in which all of the magnetic balance sensors are driven, and the power-saving mode, i.e., the mode in which only one magnetic balance sensor is driven, with a single current sensor, achieving compatibility between a wide measurement range provided by the magnetic balance system and power saving. In particular, the present invention is effective for a current sensor employing a magnetoresistive element which has a configuration in which a feedback coil is disposed close to the magnetoresistive element. Since the sensing axis of a magnetoresistive element is oriented in an in-plane direction, a coil can be formed extremely close to the magnetoresistive element in a manufacturing process of a current sensor, resulting in an advantage that a configuration can be employed in which a relatively small feedback current can produce a magnetic field that cancels out a magnetic field produced by a large current.

### Battery Using Current Sensor

A battery using a current sensor according to an embodiment of the present invention includes a battery body which is provided with a current line, and a current sensor which is attached to the current line. Description will be made for the case in which a battery having such a configuration is managed by performing charge and discharge control, that is, by a battery management system.

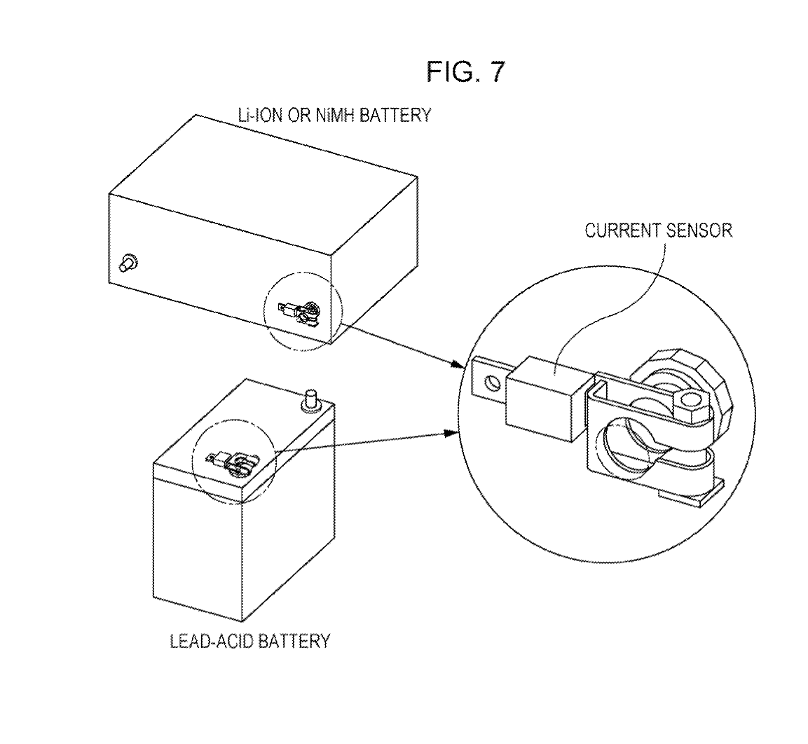

A current sensor described in the embodiment is provided for a battery, thereby enabling management of the battery. Specifically, as illustrated in FIG. 7, a current sensor is attached to a terminal, i.e., the positive electrode or the minus electrode, of a battery that is subjected to charge and discharge, such as a Li-ion battery, a NiMH battery, or a lead-acid battery. The current sensor is used to measure current caused by the charge and discharge in the battery, and the measurement results are summed, thereby enabling management of a remaining quantity of the battery.

The value of a current which flows when the battery is used is significantly different from the value of a current which flows when the battery is not used. By using a current sensor according to an embodiment of the present invention, in other word, by selecting the power-saving mode for a small measurement current and selecting the normal mode, i.e., the differential detection by the magnetic balance system, for a measurement current larger than the small measurement current, a single current sensor can detect an amount of current with high accuracy in both the cases where the battery is used and where the battery is not used. By measuring a value of battery current with high accuracy, summation error can be reduced, thereby decreasing a margin which is provided for the battery in order to prevent an overcharge or an over-discharge. As a result, the battery can be efficiently used. For example, a current sensor according to the embodiment of the present invention is applied to a battery such as one in an electric car, enabling the mileage for the battery to be increased.

The present invention is not limited to the above-described embodiment, and various modifications can be made and embodied. For example, in the above-described embodiment, the case where a current sensor using the magnetic balance system is used is described. The present invention can be applied also to the case where a current sensor using a magnetic proportional system is used. That is, the present invention can be applied also to the case where the power-saving mode is on for a small measurement current and the normal mode, i.e., the differential detection by the magnetic proportional system, is on for a measurement current larger than the small measurement current. In addition, the connection relationships, the sizes, the values, or the like of the components in the above-described embodiment may be modified as appropriate and embodied. In the embodiment described above, a magnetic balance current sensor employing magnetoresistive elements is described. Alternatively, a magnetic balance current sensor employing Hall elements or other magnetic detection devices may be used. In addition, the present invention can be embodied with modifications as appropriate without departing the scope of claims of the present invention.

The present invention can be applied to a current sensor which detects the magnitude of current for driving a motor in an electric car or a hybrid car.

What is claimed is:

1. A current sensor comprising:
a plurality of magnetic balance sensors each including
a magnetic sensor element varying in characteristics due to an induction field caused by measurement current, and
a feedback coil disposed near the magnetic sensor element, the feedback coil producing a canceling magnetic field canceling out the induction field,
wherein each of the magnetic balance sensors outputs, as a sensor output, a value corresponding to current flowing through the feedback coil when a balanced state in which the induction field and the canceling magnetic field cancel each other out is reached after the feedback coil is energized; and
switching means for turning on/off magnetic balance sensors other than one of the plurality of magnetic balance sensors.

2. The current sensor according to claim 1,
wherein a pair of magnetic balance sensors are disposed so as to face each other with a conductor interposed therebetween, the conductor being configured in such a manner that the measurement current flows through the conductor, and sensing axis directions of the magnetic sensor elements in the pair of magnetic balance sensors are identical.

3. The current sensor according to claim 1,
wherein the switching means is provided for turning on/off the magnetic balance sensors other than one of the plurality of magnetic balance sensors in accordance with an external signal.

4. The current sensor according to claim 1,
wherein the magnetic balance sensors other than one of the plurality of magnetic balance sensors are turned off in a range of a relatively small measurement current.

5. The current sensor according to claim 1,
wherein a signal is output to the outside, the signal indicating an on/off state of the magnetic balance sensors other than one of the plurality of magnetic balance sensors.

6. The current sensor according to claim 1,
wherein the magnetic sensor element is a magnetoresistive element.

7. A battery comprising:
a battery body provided with a current line; and
the current sensor according to claim 1 attached to the current line.
